(19) United States
(12) Patent Application Publication
(10) Pub. No.: US 2018/0013381 A1
(43) Pub. Date: Jan. 11, 2018

(54) AIRSHIP EQUIPPED WITH A COMPACT SOLAR GENERATOR USING LOCAL CONCENTRATION AND BIFACIAL SOLAR CELLS

(71) Applicant: THALES, COURBEVOIE (FR)

(72) Inventor: THIERRY DARGENT, CANNES LA BOCCA (FR)

(21) Appl. No.: 15/588,325

(22) Filed: May 5, 2017

(30) Foreign Application Priority Data
Jul. 8, 2016 (FR) 1601064

(51) Int. Cl. H02S 40/22; H01L 31/068; B64B 1/06; H02S 99/00; H02S 10/40

(52) U.S. Cl. CPC H02S 40/22; H02S 99/00; H02S 10/40; B64B 1/06; H01L 31/0684

(57) ABSTRACT

An airship is equipped with a compact solar generator using concentration to supply the airship in flight with electrical energy from solar radiation. The compact solar generator comprises a first set of row(s) of bifacial photovoltaic solar cells, arranged parallel to a longitudinal central axis of the airship, and a solar radiation concentrator for making solar rays converge towards rear faces of the bifacial solar cells of the first set. The solar radiation concentrator is a second set of one or more local solar radiation concentrator(s), wherein each local concentrator is paired with a corresponding row of solar cells and comprises a reflector of convex form suitable for making solar radiation converge towards the rear faces of the solar cells of the paired row.

### CROSS-REFERENCE TO RELATED APPLICATIONS

This application claims priority to foreign French patent application No. FR 1601064, filed on Jul. 8, 2016, the disclosure of which is incorporated by reference in its entirety.

### FIELD OF THE INVENTION

The present invention relates to an airship, equipped with a compact solar generator using rows of bifacial solar cells.

The field of the invention relates to the solar generators using solar radiation concentration, intended, after installation, to supply an airship with electrical energy and to make said airship independent from an energy point of view with respect to its propulsion and the powering of its systems embedded on board.

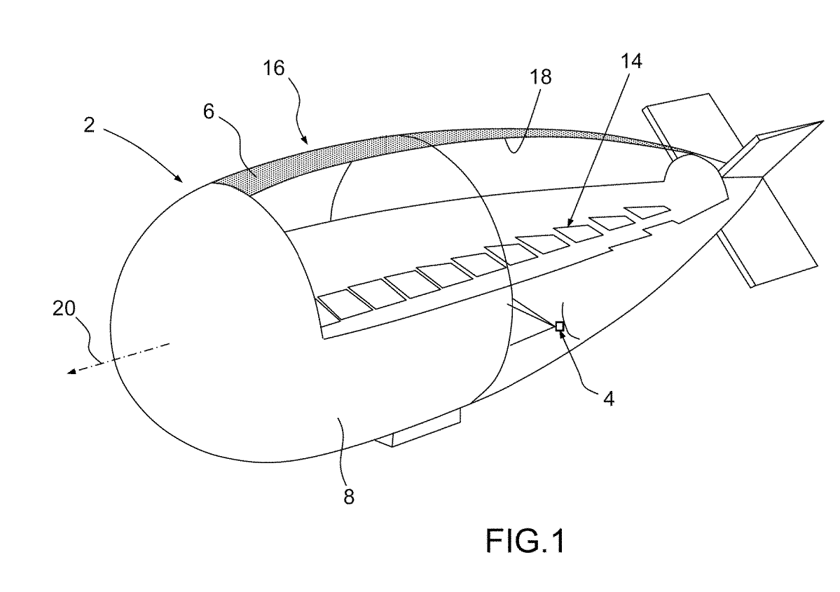

More particularly, the invention applies to an autonomous stratospheric platform project currently under development, called “stratobus” and designed to maintain a stationary position by withstanding permanently, that is to say 24 hours out of 24 hours, the outer pressure forces exerted by the high-altitude winds. As illustrated in FIG. 1 and as is known, a stratospheric airship 2 of this type is of large size and implements a high-power electrical propulsion system 4, that is to say, for example, a system of propellers driven by one or more electric motors, which use very large solar panels 6. For example and typically, the airship has an elongate form in a longitudinal direction and has an outer envelope 8 contained within a cylindrical template of approximately 100 metres in length and 30 metres in diameter. Such a airship 2 size corresponds to an electrical energy need equal to approximately one hundred kilowatts.

### BACKGROUND

The current solar generator solutions, proposed to provide such a high quantity of electrical energy, use, as represented in FIG. 1, a solar panel 6 equipped with bi- or mono-facial solar cells and a solar radiation concentrator 14, the assembly forming a solar generator 16 with radiation concentrator.

According to these known solutions and FIG. 1, the solar panel 6 of the solar generator 16 is arranged at the apex 18 of the airship 2 whereas the radiation concentrator 14 is arranged and installed inside the outer envelope 8, a significant distance away from the apex 18 of the outer envelope 8. For example, the radiation concentrator 14 is arranged longitudinally close to a longitudinal central axis 20 of the airship as illustrated in FIG. 1 or at a level below the longitudinal axis moving away from the apex of the outer envelope 8.

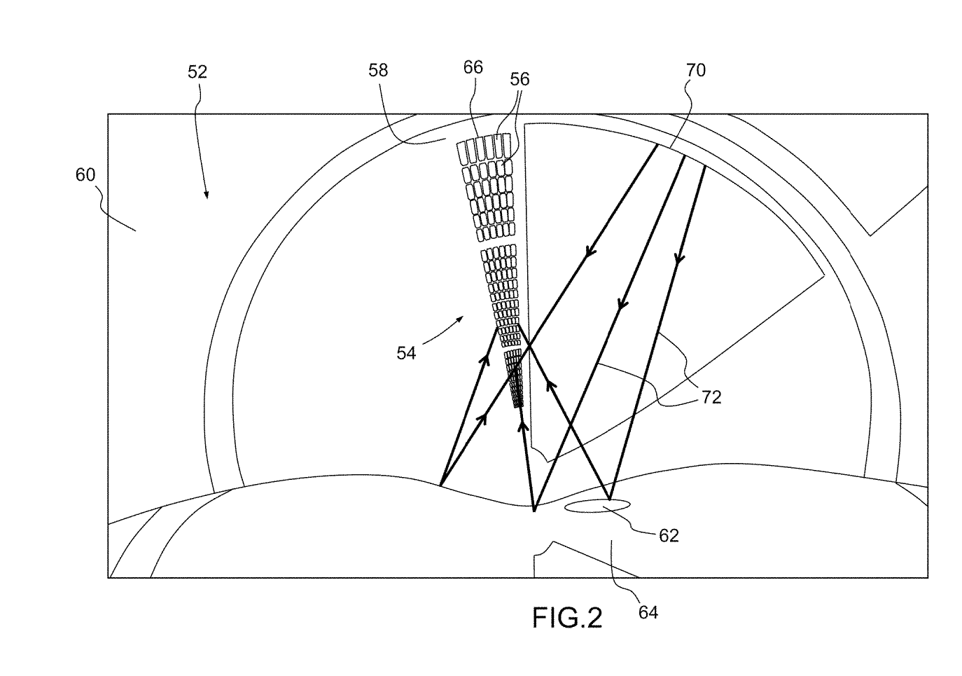

According to FIG. 2 and the French Patent application, filed on 15 Jul. 2015 under the filing number 1 501486, and entitled “Airship equipped with a solar generator with concentration and using an arrangement of solar cells, optimized to power said airship in flight”, a airship 52 with solar generator 54 using concentration, seen from the inside thereof, comprises and uses bifacial solar cells 56, arranged at the apex 58 of its outer envelope 60. The solar generator 54 comprises a solar radiation concentrator 62, arranged inside the outer envelope 60 and installed flexibly on a first bottom zone 64 of the outer envelope 60 facing the apex 58 of the same outer envelope 60. The outer envelope 60 comprises, towards the apex 58, on either side of the bifacial solar cells 56 arranged in a strip 66, a second transparent zone 70 to allow the solar rays 72 to pass towards the radiation concentrator 62.

This solution presents the following drawbacks. Firstly, the radiation concentrator, installed in and fixed to the outer envelope of the airship, is difficult to produce, on the one hand in terms of observance of geometrical requirements of accuracy of placement of said concentrator with respect to the solar cells in a flexible outer envelope subjected to deformations, and on the other hand in terms of integration in an outer envelope that is also sealed. Secondly, from a point of view of the overall design of the airship, that is to say at the highest level of the design of the system, this configuration of a radiation concentrator located inside the outer envelope, couples the constraints of design of the outer envelope with those of design of the solar generator, which makes obtaining a solution that is simple to implement complicated and renders the system difficult to test. Thirdly, at the electrical power generation level, the current solar generator system requires an outer envelope that is transparent, at least over a zone of its upper part, which reduces the efficiency of the solar generator because of the absorption of the solar radiation that occurs on passing through the walls of the envelope and limits the cooling by infrared radiation of the rear face of the solar cells, a material that is transparent in the visible range not being transparent in the infrared range. Furthermore, since the material of the envelope has to be both transparent and mechanically very strong over a long lifetime, that is to say, here, over at least five years, there are still technological production difficulties to be overcome and which add to the problems. Fourthly, allowing the solar radiation to enter into the airship causes an internal heating of the airship which increases the internal pressure thereof and dictates over dimensioning the mechanical strength of the envelope.

### SUMMARY OF THE INVENTION

The present invention aims to overcome the abovementioned drawbacks.

The technical problem is how to provide a solar generator that is lighter, simple to produce, more efficient in terms of efficiency of electrical energy supply delivered per surface unit of solar cells, with a minimum of mechanical and thermal interaction with the envelope of the airship.

To this end, the subject of the invention is an airship, equipped with a compact solar generator using concentration to supply said airship in flight with electrical energy from solar radiation, the airship comprising an outer envelope, a gas bearer contained in the outer envelope, and a compact solar generator using concentration, the outer envelope having a closed outer surface of elongate form along a predetermined longitudinal central axis. The compact solar generator comprises:

a first set of at least one row of bifacial photovoltaic solar cells, arranged above and at a predetermined height h from a compact portion of apex of the outer surface, in which each row of bifacial solar cells is configured to follow, overhanging, a longitudinal path, plotted on the compact portion of apex of said outer surface and contained in a radial projection plane containing the longitudinal central axis of the outer surface; and

a solar radiation concentrator for converging solar rays towards rear faces of the bifacial solar cells of the first set.

The airship is characterized in that:

the solar radiation concentrator is a second set of at least one local solar radiation concentrator, in which each local concentrator is paired with a corresponding row of solar cells, and comprises a reflector of which a first reflecting face has a surface of convex form suitable for making solar radiation converge towards the rear faces of the solar cells of the paired row, and of which a second concave face, behind the first convex face, is fixed to the outer surface of the outer envelope along the longitudinal path overhung by the corresponding row of solar cells, and

the first and second faces of the local solar radiation concentrators are dimensioned and arranged between them so as to leave the concentrators separate or adjacent.

According to particular embodiments, the airship, equipped with a solar generator using concentration, comprises one or more of the following features:

the geometry of the rows of the solar cells and of the faces of the local concentrators is adjusted so as to ensure a solar flux that is constant and of the same intensity independent of the position of the photovoltaic solar cell on the portion of outer surface;

each bifacial cell has a front face and a rear face, and the bifacial cells of the rows of the first set are arranged in terms of positioning and of orientation relative to the portion of outer surface of the airship on which the cells are fixed such that the normals of the front faces of all the solar cells point towards a same predetermined direction of illumination relative to the airship;

the surface of the first reflecting convex face of each local concentrator comprises a first strip masked by the solar cells of the associated row, second and third active strips participating in the concentration of the solar radiation, the first and second active strips consisting of a material that is reflective to the radiation contained in the frequency bands involved in the photovoltaic conversion, and the first masked strip consisting of a material that is reflective to the thermal radiation emitted by the photovoltaic cells when they are active;

the surface of the first reflecting convex face of each local concentrator is made entirely of a material that is both reflective to the radiation contained in the frequency bands involved in the photovoltaic conversion, and reflective to the thermal radiation emitted by the photovoltaic cells and the sun;

each row of solar cells of the first set is fixed to the portion of outer surface of the outer envelope through the associated local concentrator and a pile work of posts, interposed and fixed between the row of the photovoltaic cells and the paired local concentrator, the material forming the posts being rigid, electrically insulating and with low absorbance to solar radiation;

the surfaces of the first reflecting convex faces have outlines of longitudinal cross section with the form of a conical portion or a curve approximating a conical portion;

the surfaces of the first reflecting convex faces have outlines of longitudinal cross section in the form of a succession of an odd integer number N of segments approximating a conical portion, the odd integer number N of segments preferably being included in the integers 3, 5 and 7;

the ratio of the height of overhang h of the rows of solar cells to the distance r separating the portion of outer surface of the longitudinal central axis of the outer surface is less than or equal to 1/15, preferably less than or equal to 1/30;

the compact solar generator comprises an integer number NL of rows of solar cells and of local concentrators, and each local concentrator is subdivided into a longitudinal sequence of an integer number T, greater than or equal to 2, of longitudinal sections of local concentrator, paired either in a first case with a straight row of solar cells of same radial level relative to the longitudinal axis, or in a second case to a row of solar cells segmented into different radial levels relative to the longitudinal axis;

each longitudinal section comprises an elementary reflector of which a first elementary reflecting face has a surface of convex form suitable for making the solar radiation converge towards the rear faces of the solar cells of the paired row of same longitudinal level and of which a second elementary face, rear and concave, is fixed to the portion of outer surface of the outer envelope along the longitudinal path overhung by the paired row of solar cells;

the geometry of the rows of solar cells and of the faces of the longitudinal sections of the local concentrators is adjusted so as to ensure a solar flux that is constant and of same intensity independent of the position of the photovoltaic solar cell on the portion of outer surface;

the surface of the first elementary reflecting face of each section of local concentrator comprises a first elementary strip masked by the solar cells of same longitudinal level of the paired row, second and third active elementary strips participating in the concentration of the solar radiation, the first and second active elementary strips being made of a material reflective to the radiation contained in the frequency bands involved in the photovoltaic conversion, and the first masked elementary strip being made of a material reflective to the thermal radiation emitted by the photovoltaic cells when they are active;

the surfaces of the first reflecting convex elementary faces have outlines of longitudinal cross section in the form of a conical portion or a curve approximating a conical portion;

the surfaces of the first reflecting convex elementary faces have outlines of longitudinal cross section in the form of a succession of an odd integer number N of segments approximating a conical portion, the odd integer number N of segments preferably being included in the integers 3, 5 and 7.

The invention will be better understood on reading the following description of several embodiments, given purely by way of example and with reference to the drawings in which:

FIG. 1 is an outer view of an airship, equipped with and incorporating a solar generator using solar radiation concentration according to the prior art;

FIG. 2 is an interior view of the airship according to the prior art of FIG. 1, taken from inside the outer envelope of the airship;

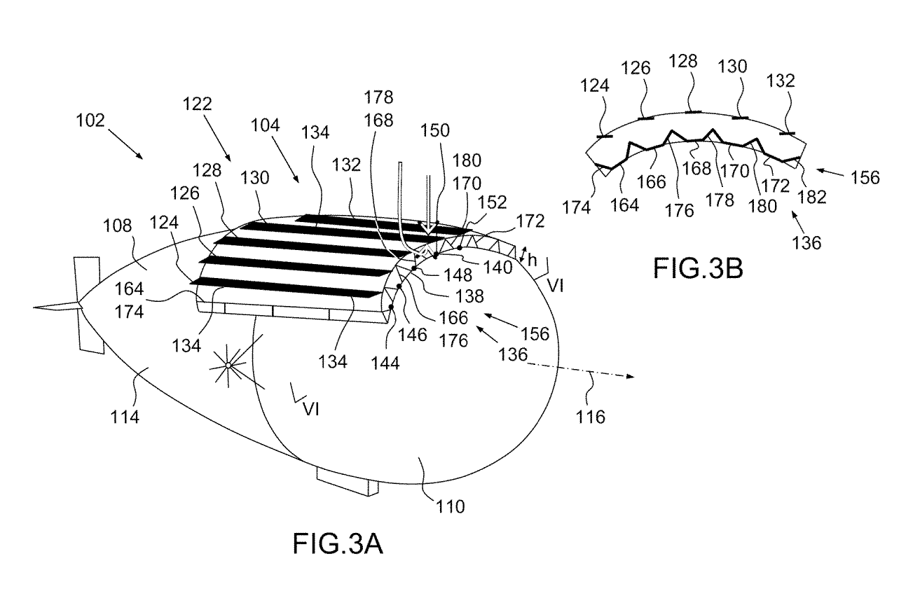

FIG. 3A is a perspective view of an airship, equipped with and incorporating a compact solar generator using radiation concentration according to a general embodiment of the invention;

FIG. 3B is a partial front view, at right angles and end-on relative to the longitudinal axis of the airship, of the solar generator incorporated in the airship of FIG. 3A;

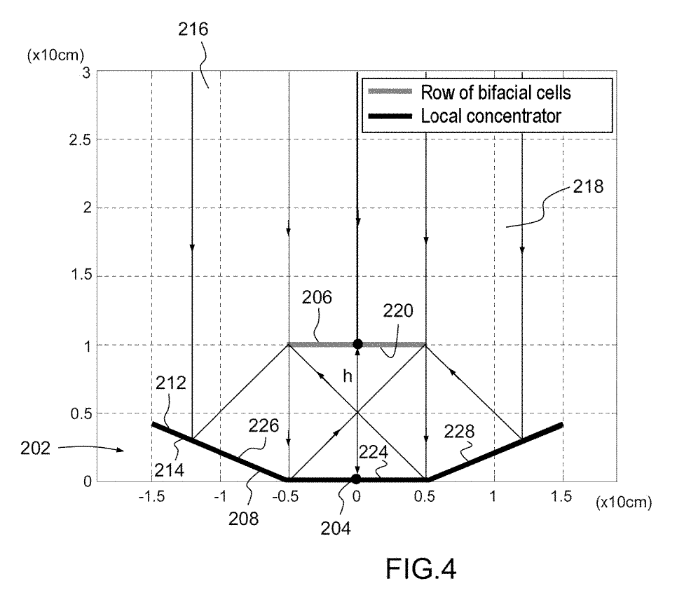

FIG. 4 is a schematic cross-sectional view of a first particular embodiment of a local concentrator of the compact solar generator of FIG. 3, paired with its row of solar cells, in the case where the portion of outer surface covered by the compact solar generator can be likened to a single tile of a cylinder of longitudinal extension, and in a configuration of placement at the apex of the envelope of the airship;

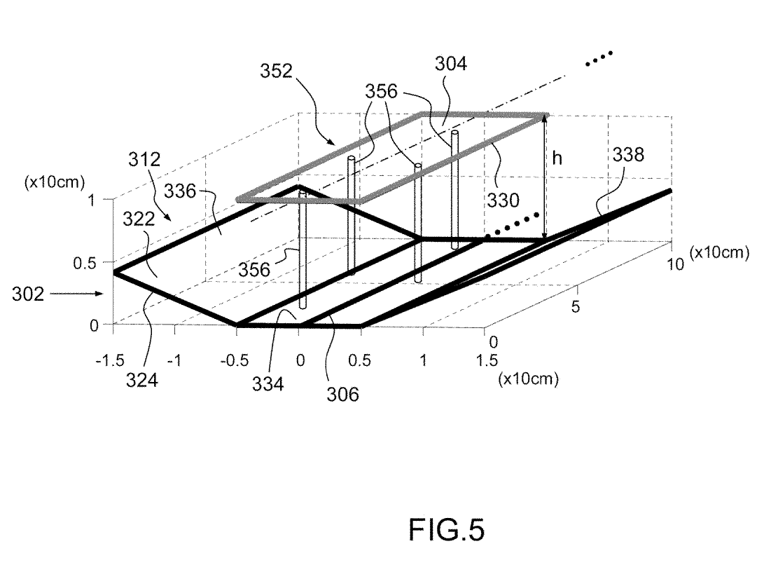

FIG. 5 is a partial three-dimensional schematic view of a second particular embodiment of a local concentrator of the compact solar generator of FIG. 3, subdivided into a number T of longitudinal sections, paired with its row of solar cells, in the case where the portion of outer surface covered by the compact solar generator can be likened to a longitudinal succession of T tiles of cylinders whose diameters can vary, a single longitudinal section being illustrated in a configuration of placement at the apex of the envelope of the airship;

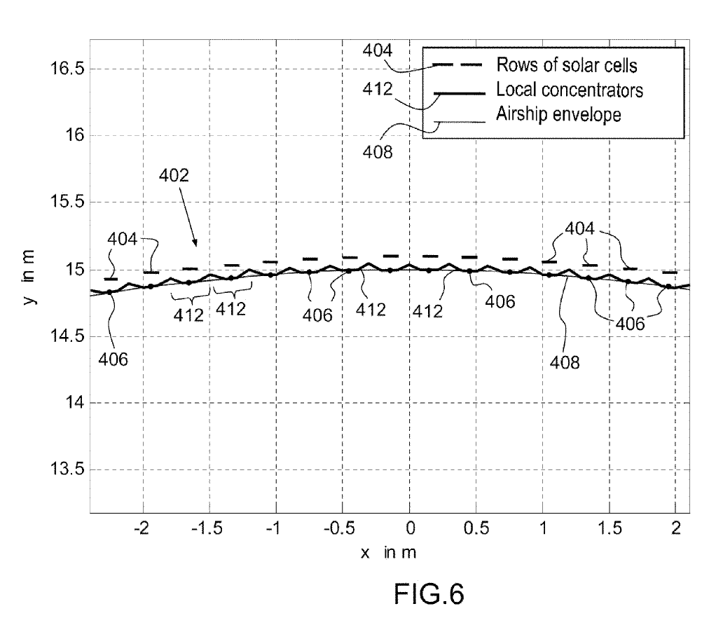

FIG. 6 is a partial view in cross section of a compact solar generator according to the invention of FIG. 3A along the cutting plane VI-VI of FIG. 3A, in which the local concentrators are defined according to one of the patterns of embodiments of FIGS. 4 and 5, and in which the inclinations of the faces of the solar cells and of the reflecting return faces of the local concentrators relative to the local planes of fixing to the outer envelope are adjusted according to their placement to optimize the concentration efficiency of the compact solar generator;

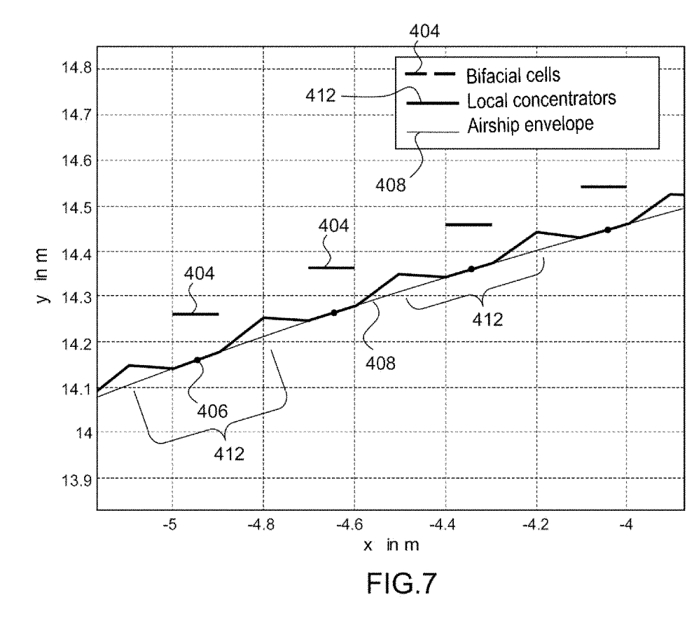

FIG. 7 is a partial view in cross section of the same compact solar generator as that of FIG. 6 in a zone further away horizontally from the top of the airship and on a larger scale;

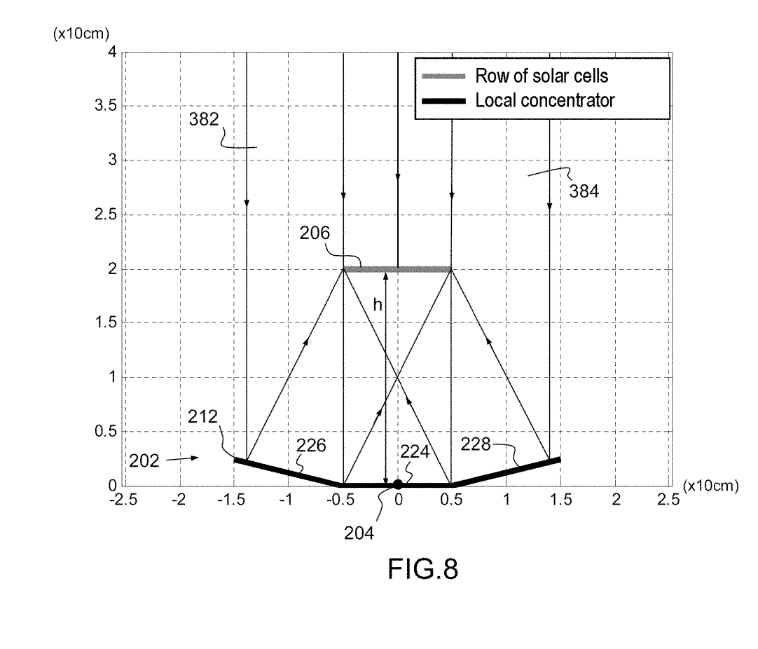

FIG. 8 is a schematic cross-sectional view of a variant of the first embodiment of the local concentrators according to FIG. 4 in which the height h of overhang of the rows of solar cells, and consequently the thickness of the solar generator, is modified to increase the efficiency of the set of local concentrators.

### DETAILED DESCRIPTION

The underlying concept of the invention consists in replacing the solar generator according to the prior art whose global solar concentrator is incorporated inside the outer envelope of the airship with a compact solar generator, using local radiation concentration, of small thickness compared to the diameter of the airship, in which a set of local concentrators is arranged outside and at the apex of the outer envelope of the airship. The local concentrators are situated below and as close as possible to the bifacial cells, hug and follow the surface of the airship while ensuring an effective bifacial concentration of the solar radiation towards the solar cells in order to maximize the energy efficiency of the global solar panel.

Thus, this compact solar generator solution using local concentration, installed entirely outside the airship, makes it possible to remedy the abovementioned technical problems presented by the current solar generator systems, without in any way disrupting the aerodynamics and the thermics of the airship because of the small thickness of the solar generator compared to the diameter of the airship and because of the absence of direct contact of the hot parts of the solar generator, that is to say the solar cells, with the envelope of the airship.

According to FIG. 3A and a general embodiment of the invention, an airship 102 is equipped with a compact solar generator 104 using local concentration to supply said airship 102 in flight with electrical energy from solar radiation.

The airship 102 comprises an outer envelope 108, a gas bearer 110 contained in the outer envelope 108, and the compact solar generator 104 using local solar radiation concentration.

The outer envelope 108 comprises a closed outer surface 114 of elongate form along a predetermined longitudinal central axis 116.

According to FIGS. 3A and 3B, the compact solar generator comprises a first set 122 of at least one row 124, 126, 128, 130, 132 of bifacial photovoltaic solar cells 134, and a solar radiation concentrator 136 for making solar rays converge towards rear faces of the bifacial solar cells 134 of the first set 122.

The first set 122 of the rows 124, 126, 128, 130, 132 of solar cells 134 is arranged above and at a predetermined height h from a compact portion 138 of apex 140 of the outer surface 114, in which each row 124, 126, 128, 130, 132 of bifacial solar cells 134 is configured to follow respectively, overhanging, a longitudinal path 144, 146, 148, 150, 152, plotted on the compact portion 138 of apex 140 of said outer surface 114 and contained in a corresponding radial projection plane, not represented in FIG. 3A, containing the longitudinal axis 116 of the outer surface 114.

According to FIGS. 3A and 3B, the solar radiation concentrator 136 is a second set 156 of at least one local solar radiation concentrator 164, 166, 168, 170, 172, in which each local concentrator 164, 166, 168, 170, 172 is paired with a corresponding row 124, 126, 128, 130, 132 of solar cells, having a reflector 174, 176, 178, 180, 182 of which a first reflecting face has a surface of planar or concave or convex form, here convex in the figure, suitable for making the solar radiation converge towards the rear faces of the solar cells of the corresponding row 124, 126, 128, 130, 132 and of which a second planar or concave face, here concave in the figure, behind the first convex face, is fixed to the outer surface of the outer envelope along the longitudinal path of the envelope of the airship overhung by the corresponding row 124, 126, 128, 130, 132 of solar cells.

The first and second faces of the local solar radiation concentrators 164, 166, 168, 170, 172 are dimensioned and arranged between them so as to leave the local concentrators 164, 166, 168, 170, 172 separate or adjacent.

Generally, the geometry of the rows of the solar cells and of the faces of the local concentrators is adjusted so as to ensure a solar flux that is constant and of same intensity independent of the position of the photovoltaic solar cell on the portion of outer surface.

The geometry can be defined notably by the form and the dimensions of the reflecting faces of the local concentrators, but also by inclinations of the reflecting faces of a local concentrator relative to the tangential local plane of fixing of the local concentrator to the outer envelope.

Generally, the surface of the first reflecting convex face of each local concentrator comprises a first strip of surface masked by the solar cells of the associated row, second and third strips of active surfaces participating in the concentration of the solar radiation. The second and third strips of active surfaces are made of a material reflective to the radiation contained in the frequency bands involved in the photovoltaic conversion and in infrared for the thermal radiation. The first masked surface strip is made of a material reflective to the thermal radiation emitted by the photovoltaic cells when they are active.

Particularly and preferably, the surface of the first reflecting convex face of each local concentrator is made entirely of a material both reflective to the radiation contained in the frequency bands involved in the photovoltaic conversion, and reflective to the thermal radiation emitted by the photovoltaic cells and the sun. For example, the three surfaces of the first convex face are made of a same silvered plastic material (deposition of a film of silver).

Generally, the surfaces of the first reflecting convex faces have outlines of longitudinal cross section in the form of a conical portion or a curve approximating a conical portion.

Generally, each row of solar cells of the first set is fixed to the portion of outer surface of the outer envelope through the associated local concentrator and a pile work of posts, not represented in FIGS. 3A and 3B, interposed and fixed between the row of photovoltaic cells and the paired local concentrator. The material forming the posts is rigid, electrically insulating and of low absorbance to solar radiation.

Thus, and unlike the solar generator of the prior art described in FIGS. 1 and 2, the outer envelope 108 of the airship 102 does not require the existence of a transparent zone to allow the rays of the sun to pass and allow them to reach a radiation concentrator arranged inside said envelope.

Consequently and according to FIG. 1 with the rays of the sun 192, 194 not passing through the outer envelope 108 of the airship, there is no attenuation of the incident solar flux, nor any internal heating of the airship. Similarly, the radiative cooling of the rear face of the bifacial cell is facilitated and is done without passing through the wall of the envelope of the airship, which is opaque to the infrared.

Furthermore, since the bifacial solar cells are mechanically and thermally decoupled from the outer envelope of the airship, they do not directly heat up said airship by conduction or by radiation.

Furthermore, since the compact solar generator using local concentration is entirely external to the airship, it can be manufactured and tested independently of the subsystem, formed by the envelope, and installed subsequently during the integration of the airship.

According to FIG. 4 and a schematic example of a first embodiment of a local concentrator 202, the local concentrator 202, seen in cross section, is assumed here to be situated at the apex of the airship, and to follow, over the portion of outer surface of the envelope, a rectilinear path 204, overhung by a corresponding paired row 206 of bifacial solar cells. Here, the curvature of a strip of the outer surface of the airship, some ten centimetres wide, situated around and in the vicinity of the rectilinear path 204, is assumed close to that of a plane. The direct solar illumination of the cells of the row 206 is assumed to originate vertically from above in FIG. 4, at right angles to the plane tangential to the path 204 at the apex of the airship.

The local concentrator 202 comprises a reflector 208 having a first reflecting face 212 and a second rear face 214.

The first reflecting face 212 has a convex form suitable for making the solar radiation of two incident beams 216, 218 converge towards the rear faces 220 of the bifacial solar cells of the row 206.

The second rear face 214 has a concave face, fixed along the longitudinal path 204.

The first reflecting face 212 comprises a first strip 224 of surface, here planar, masked by the solar cells of the associated row 206, second and third strips 226, 228, here planar, of active surfaces participating in the concentration of the solar radiation, here the incident beams 216, 218 towards the rear faces of the cells of the row 206.

As a variant, the surfaces of the first reflecting convex faces have outlines of longitudinal cross section in a form that is a succession of an odd integer number N greater than or equal to 5, of segments approximating a conical portion.

Preferably, the integer number N of segments is preferably included among the integers 3, 5 and 7.

The local concentrator 202, through its simple form as a succession of segmented planar mirrors, can be produced from metal foils, for example made of aluminium, or any other material making it possible to produce a mirror for the solar radiation at least in the band of frequencies active for the photovoltaic conversion and in the thermal radiation band.

Concerning the first masked strip 224, it is not involved in the concentration of the photovoltaic radiation, and it may be sufficient for the constituent material thereof to be capable of reflecting the thermal radiation emitted by the bifacial photovoltaic conversion solar cells. In effect, the bifacial solar cells emit an intense thermal flux towards the outer envelope and the first masked strip 224 of the reflector 212, through its thermal properties, makes it possible to reflect the intense thermal flux towards the outside of the airship.

According to FIG. 4 and by way of example, the width of a photovoltaic cell of the row 206 is equal to 10 cm whereas the height h of overhang relative to the rectilinear path 204 followed along the portion of outer surface is equal to 10 cm. The widths of the mirror flaps formed by the first, second and third strips are each equal to 10 cm. The inclinations of the second and third strips are adjusted relative to the first strip so as to maximize the concentration factor which here is equal to 2.41, the concentration factor being defined as the ratio of the sum of the solar fluxes received by the front face and the rear face of the bifacial solar cell to the solar flux received by the front face alone.

It should be noted that the form of a pair formed by row of solar cells and local concentrator, having the same pattern as the pair formed by row 204 and local concentrator 202 and separated angularly therefrom by a predetermined angle α, and optimizing the supply of electrical energy from the solar cells of its row, is obtained by securely pivoting the pair formed by the row 204 of solar cells and local concentrator 202 about the longitudinal median axis of the first strip of the predetermined angle α, the direction of direct solar illumination being unchanged, that is to say vertical in FIG. 4, then inclining the faces of the row 204 about their common longitudinal median axis so as to align the normals of the front faces of the cells with the predetermined direction of solar illumination, and then adjusting the inclinations of the second and third strips relative to the first strip so as to maximize the return of the solar radiation onto the rear faces of the solar cells of row 204 whose inclination has been previously adjusted.

According to FIG. 5 and a schematic example of a second embodiment of a local concentrator 302, assumed here to be situated at the apex of the outer envelope of the airship, the local concentrator 302 is subdivided into a longitudinal sequence of an integer number T, greater than or equal to 2, of longitudinal sections of local concentrator, paired either in a first case with a straight row of solar cells of same radial level, or in a second case with a row of solar cells segmented into different radial levels relative to the longitudinal axis according to the longitudinal level.

The first case corresponds, like FIG. 4, to a portion of outer surface of the airship covered by the compact solar generator, similar to a single tile of a cylinder of longitudinal extension.

The second case corresponds to a portion of outer surface of the airship covered by the compact solar generator, similar to a longitudinal succession of T tiles of cylinders whose diameters are different and vary according the longitudinal level.

The row of the solar cells, paired with the local concentrator 302, is designated by the numeric reference 304.

The local concentrator 302 is assumed here to follow, over the portion of outer surface of the envelope, a path 306 whose radial level is constant or varies a little by levels of length identical to that of a tile, the path being overhung at a constant height h by the corresponding row 304 of solar cells. Here, the curvature of a strip of the outer surface of the airship, some ten centimetres wide, situated around and in the vicinity of the rectilinear path 304, is assumed close to that of a plane.

According to FIG. 5, a single section 312 out of the T sections of the local concentrator 302 is illustrated. The section 312 shares a same pattern with the other sections of the local concentrator, and with the sections of the other local concentrators. The geometry of the pattern is unchanged in the first case of portion of outer surface covered and varies in the second case according to the diameter of the tile covered out of the T tiles.

The section 312 of local concentrator comprises an elementary reflector having a first reflecting elementary face 322 and a second elementary rear face 324.

The first elementary reflecting face 322 has a convex form suitable for making the solar radiation of two incident beams, not represented in FIG. 5, converge towards the rear faces 330 of the bifacial solar cells of the row 304 situated at the same longitudinal level.

The second rear elementary face 324 has a concave face, fixed to the portion of the outer surface of the outer envelope along the longitudinal path 306.

The first elementary reflecting face 322 comprises a first elementary strip 334 of surface, here planar, masked by the solar cells of the associated row 304, second and third elementary strips 336, 338, here planar, of active surfaces participating in the concentration of the solar radiation towards the rear faces of the cells of the row 304.

As a variant, the surfaces of the first reflecting convex elementary faces have outlines of longitudinal cross section in a form that is a succession of an odd integer number N, greater than or equal to 5, of segments approximating a conical portion.

Preferably, the integer number N of segments is preferably included among the integers 3, 5 and 7.

The T longitudinal sections of the local concentrator 302, through their simple form as a succession of segmented elementary planar mirrors, can be produced by metal foils, for example made of aluminium, or any other material making it possible to produce a mirror for the solar radiation at least in the band of frequencies active for the photovoltaic conversion.

Concerning the first masked elementary strip 334, it is not involved in the concentration of the photovoltaic radiation, and it can be sufficient for the constituent material thereof to be capable of reflecting the thermal radiation emitted by the bifacial photovoltaic conversion solar cells. In effect, the bifacial solar cells emit an intense thermal flux towards the outer envelope and the first masked elementary strip 334 of the reflector 322, through its thermal properties, makes it possible to reflect the intense thermal flux towards the outside of the airship.

According to FIG. 5, the width of a photovoltaic cell of the row 304 is equal to 10 cm whereas the height h of overhang relative to the rectilinear path 306 followed along the portion of outer surface is equal to 10 cm. The widths of the mirror flats formed by the first, second and third elementary strips are each equal to 10 cm, their common length being here equal to 1 metre. The inclinations of the second and third elementary strips are adjusted relative to the first elementary strip so as to maximize the concentration factor.

According to FIG. 5, the row of solar cells 304, paired with the local concentrator 302, is fixed to the portion of outer surface of the outer envelope through each section of the local concentrator 302, and a pile work 352 of posts 356, interposed and fixed between the row 304 of the photovoltaic solar cells and the T sections of the paired local concentrator. The material forming the posts is mechanically rigid, electrically insulating and of low absorbance to solar radiation.

Here, only four posts 356 of the pile work are represented, fixing the row 304 of the solar cells to the section 312 of the local concentrator 302.

The sectioning of each local concentrator of the second set into T sections, having a pattern independent of the local concentrator and of the longitudinal level of assembly of the section, in addition to simplifying the method for manufacturing and assembling the concentrator and incorporating it in the solar generator, makes it possible to maximize the return of the solar radiation to the solar cells of the first set by adjusting the dimensions and the form of the sections according to their longitudinal placement and the radial position of the local concentrators in which they are incorporated.

As a variant, sections of local concentrators adjacent to one another and of the same longitudinal level can be grouped together and incorporated on planar panels if the curvature of the portion of outer surface at the longitudinal level concerned permits this.

According to FIG. 6 and a particular geometrical configuration of installation, a compact solar generator 402 of the type of that defined in FIGS. 3A and 3B and having local concentrators of the type of that of FIG. 4 or sections of concentrators of the type of that of FIG. 5, here comprises fifteen rows 404 of solar cells respectively overhanging fifteen segments 406 of different generatrices of a portion of a cylindrical surface 408 having the form of a tile. The cylindrical surface is, here, a cylinder of radius equal to 15 metres and the segments 406, forming rectilinear paths of the portion 408 of the outer surface of the airship and represented end-on in FIG. 6 by dots, are mutually parallel. Each row 404 is paired with a different local concentrator 412, fixed onto the portion 408 of outer surface and having a reflector 414 with three segmented planar mirrors. Like FIGS. 4 and 5, each row 404 of solar cells overhangs its associated path 406 and the median mirror flat of the reflector of paired local concentrator by a height h that is constant relative to the associated path.

The dimensions and the form of each concentrator have been adjusted to ensure an optimal return of the solar radiation towards the bifacial cells, the inclinations of the faces of the cells having been previously adjusted to make their normal parallel to a predetermined direction relative to the airship, here the vertical in FIG. 6.

According to FIG. 7 and in order to better show the adjustments of the dimensions, forms and inclinations of the solar cells and of the local concentrators relative to the envelope of the airship, a view of the solar cells and of the corresponding local concentrators, similar to that of FIG. 6 but with a greater enlargement, is supplied in which the envelope zone supporting the solar cells and the local concentrators represented is horizontally separated from the top peak line of the airship by an algebraic distance, denoted x, being between −3.6 metres and −5.2 metres.

According to FIG. 8 and a dimensional variant of the first embodiment of the local concentrators 202 of FIG. 4, the height h of overhang of the rows of solar cells, and consequently the thickness of the solar generator, is modified to increase the efficiency of the set of local concentrators. It appears in FIG. 8, by increasing the height h of overhang of the row 206 of solar cells and by adjusting the inclination of the second and third strips 226, 228 relative to the first masked strip 204, the width of the incident beams 382, 384 returned by the reflector 212 onto the rear faces of the cells is increased, and consequently the efficiency of the local concentrator 202 is increased.

Thus, by adjusting the height of overhang h, that is to say the thickness of the solar generator, it is possible to optimize the efficiency of the second set of local concentrators and consequently the thickness of the compact solar generator.

Multiple variants of the concentrators can be used in which the size of the local concentrators and their form are first of all adjusted to optimize the concentration factor to a desired value. The forms of the concentrators are then projected and re-optimized locally to maximize the return of solar flux towards the solar cells, by using an optical computation code such as, for example, “codeV”. As seen above, the simplest forms can be planar mirrors, segmented into several planes for a greater ease of production, but can also be of conical forms or similar if necessary.

Generally, the ratio of the height of overhang h of the rows of solar cells to the distance r separating the portion of outer surface of the longitudinal central axis of the outer surface is less than or equal to 1/30.

For example, the height of overhang will lie between 0.1 and 0.2 metres for a airship radius of 15 metres relative to the longitudinal axis, which corresponds to a ratio of between 1/50 and 1/75.

Generally, the stratospheric airship described above can be replaced by any other type of airship moving in other layers of the atmosphere, by keeping the features of the invention the same.

1. An airship equipped with a compact solar generator using concentration to supply said airship in flight with electrical energy from solar radiation,
the airship comprising an outer envelope, a gas bearer contained in the outer envelope, and a compact solar generator using concentration,
the outer envelope having a closed outer surface of elongate form along a predetermined longitudinal central axis,
the compact solar generator comprising
a first set of at least one row of bifacial photovoltaic solar cells, arranged above and at a predetermined height h from a compact portion of apex of the outer surface, in which each row of bifacial solar cells is configured to follow, overhanging, a longitudinal path, plotted on the compact portion of apex of said outer surface and contained in a radial projection plane containing the longitudinal central axis of the outer surface; and
a solar radiation concentrator for converging solar rays towards rear faces of the bifacial solar cells of the first set;
the airship wherein:
the solar radiation concentrator is a second set of at least one local solar radiation concentrator, in which each local concentrator is paired with a corresponding row of solar cells, and comprises a reflector of which a first reflecting face has a surface of convex form suitable for making solar radiation converge towards the rear faces of the solar cells of the paired row, and of which a second concave face, behind the first convex face, is fixed to the outer surface of the outer envelope along the longitudinal path overhung by the corresponding row of solar cells, and
the first and second faces of the local solar radiation concentrators are dimensioned and arranged between them so as to leave the concentrators separate or adjacent.

2. The airship equipped with a compact solar generator using concentration according to claim 1, wherein
the geometry of the rows of the solar cells and of the faces of the local concentrators is adjusted so as to ensure a solar flux that is constant and of the same intensity independent of the position of the photovoltaic solar cell on the portion of outer surface.

3. The airship equipped with a compact solar generator using concentration according to claim 1, wherein
each bifacial cell has a front face and a rear face, and
the bifacial cells of the rows of the first set are arranged in terms of positioning and of orientation relative to the portion of outer surface of the airship on which the cells are fixed such that the normals of the front faces of all the solar cells point towards a same predetermined direction of illumination relative to the airship.

4. The airship equipped with a compact solar generator using concentration according to claim 1, wherein
the surface of the first reflecting convex face of each local concentrator comprises a first strip masked by the solar cells of the associated row, second and third active strips participating in the concentration of the solar radiation,
the first and second active strips consisting of a material that is reflective to the radiation contained in the frequency bands involved in the photovoltaic conversion, and
the first masked strip consisting of a material that is reflective to the thermal radiation emitted by the photovoltaic cells when they are active.

5. The airship equipped with a compact solar generator using concentration according to claim 4, wherein
the surface of the first reflecting convex face of each local concentrator is made entirely of a material that is both reflective to the radiation contained in the frequency bands involved in the photovoltaic conversion, and reflective to the thermal radiation emitted by the photovoltaic cells and the sun.

6. The airship equipped with a compact solar generator using concentration according to claim 1, wherein
each row of solar cells of the first set is fixed to the portion of outer surface of the outer envelope through the associated local concentrator and a pile work of posts, interposed and fixed between the row of the photovoltaic cells and the paired local concentrator,
the material forming the posts being rigid, electrically insulating and with low absorbance to solar radiation.

7. The airship equipped with a compact solar generator using concentration according to claim 1, wherein
the surfaces of the first reflecting convex faces have outlines of longitudinal cross section with the form of a conical portion or a curve approximating a conical portion.

8. The airship equipped with a compact solar generator using concentration according to claim 7, wherein
the surfaces of the first reflecting convex faces have outlines of longitudinal cross section in the form of a succession of an odd integer number N of segments approximating a conical portion, the odd integer number N of segments preferably being included in the integers 3, 5 and 7.

9. The airship equipped with a compact solar generator using concentration according to claim 1, wherein
the ratio of the height of overhang h of the rows of solar cells to the distance r separating the portion of outer surface of the longitudinal central axis of the outer surface is less than or equal to 1/15, preferably less than or equal to 1/30.

10. The airship equipped with a compact solar generator using concentration according to claim 1, wherein
the compact solar generator comprises an integer number NL of rows of solar cells and of local concentrators, and
each local concentrator is subdivided into a longitudinal sequence of an integer number T, greater than or equal to 2, of longitudinal sections of local concentrator, paired either in a first case with a straight row of solar cells of the same radial level relative to the longitudinal axis, or in a second case to a row of solar cells segmented into different radial levels relative to the longitudinal axis.

11. The airship equipped with a compact solar generator using concentration according to claim 10, wherein
each longitudinal section comprises an elementary reflector of which a first elementary reflecting face has a surface of convex form suitable for making the solar radiation converge towards the rear faces of the solar cells of the paired row of same longitudinal level and of which a second elementary face, rear and concave, is fixed to the portion of outer surface of the outer envelope along the longitudinal path overhung by the paired row of solar cells.

12. The airship equipped with a compact solar generator using concentration according to claim 11, wherein
the geometry of the rows of the solar cells and of the faces of the longitudinal sections of the local concentrators is adjusted so as to ensure a solar flux that is constant and of same intensity independent of the position of the photovoltaic solar cell on the portion of outer surface.

13. The airship equipped with a compact solar generator using concentration according to claim 11, wherein
the surface of the first elementary reflecting face of each section of local concentrator comprises a first elementary strip masked by the solar cells of same longitudinal level of the paired row, second and third active elementary strips participating in the concentration of the solar radiation,
the first and second active elementary strips being made of a material reflective to the radiation contained in the frequency bands involved in the photovoltaic conversion, and
the first masked elementary strip being made of a material reflective to the thermal radiation emitted by the photovoltaic cells when they are active.

14. The airship equipped with a compact solar generator using concentration according to claim 11, wherein
the surfaces of the first reflecting convex elementary faces have outlines of longitudinal cross section in the form of a conical portion or a curve approximating a conical portion.

15. The airship equipped with a compact solar generator using concentration according to claim 14, wherein
the surfaces of the first reflecting convex elementary faces have outlines of longitudinal cross section in the form of a succession of an odd integer number N of segments approximating a conical portion, the odd integer number N of segments preferably being included in the integers 3, 5 and 7.
